(19) United States
(12) Patent Application Publication
(10) Pub. No.: US 2004/0121562 A1
(43) Pub. Date: Jun. 24, 2004

(54) Method for manufacturing a semiconductor device having multiple laminated layers of different materials

(75) Inventors: Motoaki Wakui, Kumagaya-Shi (JP); Kaoru Sasaki, Iwami-Gun (JP); Kenji Imai, Anpachi-Gun (JP); Hiroyuki Shinogi, Ora-Gun (JP); Takashi Noma, Ohta-Shi (JP)

Correspondence Address: HOGAN & HARTSON L.L.P., 500 S. GRAND AVENUE, SUITE 1900, LOS ANGELES, CA, 90071-2611, US

(73) Assignees: Sanyo Electric Co., Ltd.; Kanto Sanyo Semiconductors Co., Ltd.

(21) Appl. No.: 10/714,497

(22) Filed: Nov. 14, 2003

(30) Foreign Application Priority Data
Nov. 15, 2002 (JP) 2002-332105
Mar. 27, 2003 (JP) 2003-88068

(51) Int. Cl. H01L 21/44; H01L 21/301; H01L 21/78

(52) U.S. Cl. 438/465; 438/462; 438/460; 438/114

(57) ABSTRACT

A semiconductor device manufacturing method comprises a step of forming a laminated structure by adhering, on a semiconductor substrate including a plurality of integrated circuits, a carrier member covering a region in which the plurality of integrated circuits are formed, with an insulating resin interposed between the semiconductor substrate and the carrier member, a step of cutting a notch into the laminated structure so as to cut the semiconductor substrate together with the insulating resin while allowing at least a portion of the carrier member to remain uncut, and a dicing step for dividing the laminated structure by cutting the carrier member. The notch cutting step is performed while cooling a dicing saw used to cut the semiconductor substrate.

### BACKGROUND OF THE INVENTION

1. Field of the Invention

The present invention relates to a method for manufacturing a semiconductor device having a laminated structure including multiple layers of materials having different softening temperatures.

2. Description of the Related Art

In recent years, a chip size package (CSP) is widely used to minimize the chip size of semiconductor devices. In the field of CCD image sensors, a chip size package is employed in packaging a sensor chip used in a small-size camera.

FIGS. 4A and 4B illustrate an example semiconductor device employing a chip size package. FIG. 4A shows a top perspective view of the semiconductor device, while FIG. 4B shows a bottom perspective view.

A semiconductor chip 4 is sealed between first and second carrier members 2, 3 with insulating resin layers 5 interposed between the chip 4 and the carrier members 2, 3. A plurality of ball-shaped terminals 8 are arranged on the main surface of the lower carrier member 3, in other words, on the bottom side of the device. The ball-shaped terminals 8 are connected to the semiconductor chip 4 via external wiring lines 7. Wiring drawn out from the semiconductor chip 4 is connected to the external wiring lines 7, thereby allowing the external wiring lines 7 to form contacts between the ball-shaped terminals 8 and the semiconductor chip 4.

FIG. 5 shows the steps of a method for manufacturing the device of FIGS. 4A and 4B. On a surface of a semiconductor substrate 10 having a plurality of semiconductor elements formed thereon, internal wiring 24 is formed crossing over a boundary between adjacent semiconductor elements, with an oxide film disposed between the substrate 10 and the internal wiring 24. The internal wiring 24 is electrically connected to the semiconductor elements via contact holes (S10). The semiconductor substrate 10 is next sandwiched between an upper carrier member 2 and a lower carrier member 3 with resin layers 5 interposed between the substrate 10 and the carrier members 2, 3, thereby forming a laminated structure 100 (S12). When performing this step, the semiconductor substrate 10 is etched from the lower carrier member 3 side along a scribe line to temporarily expose the internal wiring 24 before laminating the lower carrier member 3 onto the semiconductor substrate 10. Further, buffer members 30 are formed on the lower carrier member 3. The buffer members 30 serve as cushions for relieving stress applied to the ball-shaped terminals 8.

Subsequently, a notch 22 having an inverted V-shape is created in the laminated structure 100 from the lower carrier member 3 side along the scribe line using a dicing saw 34, as shown in FIG. 6, so as to expose end portions 26 of the internal wiring 24 of the elements to a side surface of the notch 22 (S14).

A metal film 28 is next formed on the surface of the lower carrier member 3 and the inner surface of the notch 22 (S16), such that the metal film 28 contacts the internal wiring 24. The metal film 28 is then patterned according to a predetermined wiring pattern to form external wiring lines 7 that extend from the internal wiring 24 to the buffer members 30 (S18). Further, a protection film 32 and ball-shaped terminals 8 are formed (S19, S20). Finally, the laminated structure 100 is divided along the scribe line to produce individual semiconductor devices packaged in a chip size package (S22).

In a CCD image sensor employing a chip size package, a light-receiving surface must be provided. Accordingly, for example, at least the upper carrier member 2 is composed of optically transparent glass, and a transparent epoxy resin is used as the resin layer for adhering the glass carrier member to the semiconductor substrate 10.

When forming a semiconductor device having a structure as described above, the metal film is deposited on a surface of a notch tilted at a predetermined angle with respect to the surface of the semiconductor substrate 10. Depositing a metal film at a high density on such a tilted surface is more difficult than depositing the same metal on the surface of the lower carrier member 3. Furthermore, because the notch 22 is formed by cutting the laminated body 100 using a dicing saw, the resins of the resin layers 5 are melted by the frictional heat, and the melted resin adheres to the inner surface of the notch 22 and the dicing saw. Roughness is thereby created on the inner surface of the notch 22. The metal film 28 cannot be successfully deposited on such an uneven surface, resulting in further undesirable decrease in the density of the deposited metal film 28.

When the density of the metal film 28 is decreased, chemical solution used to remove the resist after patterning the metal film 28 may seep into the metal film 28, causing serious problems such as corrosion and peeling of the external wiring lines 7.

Moreover, foreign substances generated by the cutting process may adhere to an end portion of the internal wiring 24, causing a contact failure at an interface between the internal wiring 24 and the external wiring 7. Furthermore, when the internal wiring 24 is composed of aluminum or the like, a hydroxide may be formed at an end portion of the internal wiring 24 during the cutting process, similarly causing a contact failure.

### SUMMARY OF THE INVENTION

The present invention provides a semiconductor device manufacturing method comprising a first step of forming a laminated structure by adhering, on a semiconductor substrate including a plurality of integrated circuits, a carrier member covering a region in which the plurality of integrated circuits are formed, with an insulating resin interposed between the semiconductor substrate and the carrier member. The method further comprises a second step of cutting into the laminated structure so as to cut the semiconductor substrate together with the insulating resin while allowing at least a portion of the carrier member to remain uncut, and a third step of dividing the laminated structure by cutting the carrier member. The second step is performed while cooling a dicing saw used to cut into the laminated structure including the semiconductor substrate.

### BRIEF DESCRIPTION OF THE DRAWINGS

FIG. 1 is a flowchart illustrating a semiconductor device manufacturing method according to a preferred embodiment of the present invention.

FIG. 2A is diagrams showing a cutting processing using a dicing saw according to the preferred embodiment.

FIG. 2B is diagrams showing a cutting processing using a dicing saw according to the preferred embodiment.

FIG. 3A is diagrams for explaining the effects of the cutting processing according to the preferred embodiment.

FIG. 3B is diagrams for explaining the effects of the cutting processing according to the preferred embodiment.

FIG. 4A is diagrams showing the external views of a chip size package semiconductor device.

FIG. 4B is diagrams showing the external views of a chip size package semiconductor device.

FIG. 5 shows the steps of a method for manufacturing a chip size package semiconductor device.

FIG. 6 is a diagram showing a cutting processing using a dicing saw as performed in a conventional semiconductor device manufacturing method.

### DESCRIPTION OF THE PREFERRED EMBODIMENT

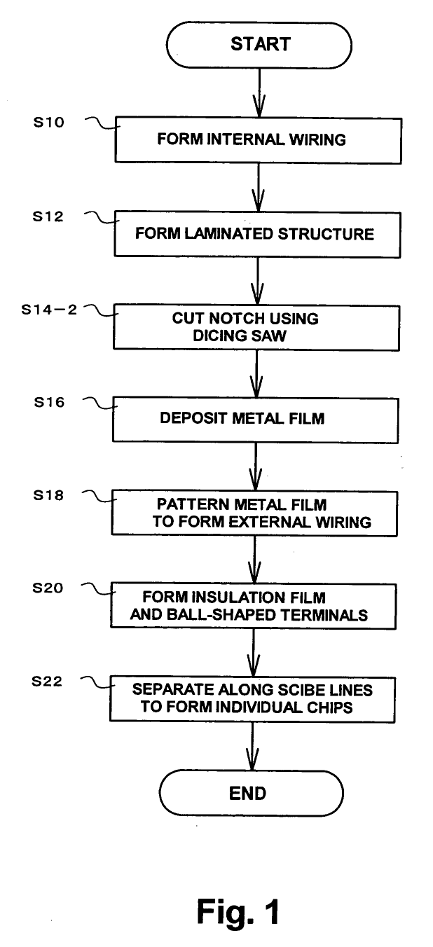

As shown in the flowchart of FIG. 1, a semiconductor device manufacturing method according to a preferred embodiment of the present invention comprises an internal wiring forming step (S10), a laminated structure forming step (S12), a notch cutting step (S14-2), a metal film depositing step (S16), a patterning step (S18), a terminal forming step (S20), and a dicing step (S22).

In the semiconductor device manufacturing method according to the present embodiment, all the steps other than the notch cutting step S14-2 are identical to those in the conventional semiconductor device manufacturing method described above. Accordingly, description of those steps will not be repeated.

The laminated structure 100 will next be explained. In the present embodiment, the semiconductor substrate 10 may be composed of a typical semiconductor material such as silicon or gallium arsenide. An integrated circuit including semiconductor elements such as a transistor element, a photoelectric conversion element, and a charge coupled device (CCD), resistor elements, and capacitor elements may be formed on the semiconductor substrate 10.

The resin layers 5, which serve to attach the semiconductor substrate 10 to the upper carrier member 2 and the lower carrier member 3, may be composed of a curing resin material such as epoxy. When forming a solid state imaging element, a transparent resin layer 5 is preferably employed.

The upper carrier member 2 and the lower carrier member 3, which serve to increase the element structural strength, may be composed of a material such as glass, metal, or plastic. When forming a solid state imaging element, at least the upper carrier member 2 is preferably formed of a transparent material such as glass or a plastic.

The improved notch cutting step, which is the characteristic feature of the present embodiment, will next be described in detail.

In the notch cutting step S14-2, a tapered dicing saw is used to cut into the laminated structure 100 from the lower carrier member 3 side to create a notch 22 having an inverted V-shape. The dicing saw cuts through the lower carrier member 3, the resin layers 5, the semiconductor substrate 10, and a portion of the upper carrier member 2, such that end portions 26 of the internal wiring 24 are exposed on the inner surface of the notch 22.

The notch cutting step may be performed using a dicing saw 34 including a disk-shaped blade having diamond microparticles attached along the blade circumference. During this step, the dicing saw 34 is cooled such that the cutting process is performed under a condition in which the temperature of the machined surface of the laminated structure 100 is maintained lower than the lowest softening temperature among the layers within the laminated structure 100.

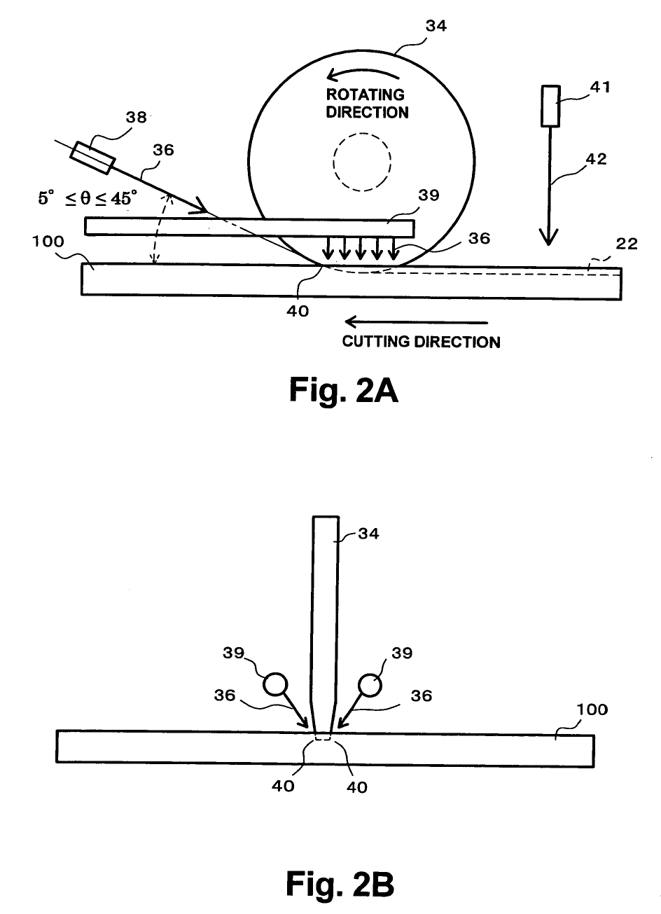

More specifically, as shown in FIGS. 2A and 2B, a cooling device including first and second coolant injectors 38, 39 is employed to inject a coolant 36 on the dicing saw 34, so as to cool the dicing saw 34 during the cutting step.

The first coolant injector 38 is located in front of the dicing saw 34 in the machining direction. As shown in FIG. 2A, the first coolant injector 38 injects the coolant 36 directly to the dicing saw 34 and the cutting portion 40. By directly spraying the coolant 36, the dicing saw 34 and the cutting portion 40 can be cooled locally, achieving favorable cooling efficiency and controlling temperature increases. The coolant 36 may be appropriately selected from suitable materials such as pure water, acetone, ethyl alcohol, isopropyl alcohol, or the like. In the present embodiment, RO water (having a pH value of approximately 7±1) obtained by purifying tap water using an RO (reverse osmosis) filter film is used as the coolant. While tap water is similarly effective from the aspect of cooling effect, chlorine included in tap water may corrode the end portions 26 of the internal wiring. For this reason, it is favorable to employ clean water such as RO water or pure water, and, in consideration of cost, use of RO water is preferable.

However, because pure water has a high resistivity, static electricity is generated when a cutting processing is performed while spraying pure water on the cutting portion, such that foreign particles are attracted to the machined surface. Further, trace amounts of substances such as ammonia and amine which produce hydroxide ions are contained in pure water and RO water, and these substances may cause formation of a hydroxide on the machined end surfaces of the internal wiring 24. For example, when the internal wiring 24 is composed of aluminum, a surface layer of aluminum hydroxide may be formed on an end surface of the internal wiring 24. This hydroxide can hinder the physical adhesive strength and the electrical contact between the end portion of the internal wiring and the subsequently formed external wiring 7.

Accordingly, it is more preferable to use a weak acid material as the coolant 36 of the present invention. The weak acid coolant 36 preferably has a pH value ranging from 4 to 6. The weak acid coolant may be, for example, carbonated water produced by bubbling carbon dioxide (CO₂) in pure water or RO water.

By using a coolant 36 having a pH value of 6 or smaller, the coolant resistivity can be lowered, thereby suppressing generation of static electricity during the cutting process. As a result, adsorption of foreign particles to the machined surface due to static electricity can be prevented. Furthermore, by using such a coolant, the end surfaces of the internal wiring 24 are etched such that, along with the etching, foreign matters adhered to the end surfaces of the internal wiring 24 can be removed. In addition, hydroxide ion sources such as ammonia or amine which may be present in pure or RO water are neutralized, thereby minimizing formation of hydroxides on the end surfaces of the internal wiring 24.

However, when the pH value is below 4, the etching of the end portions of the internal wiring 24 during the cutting process may proceed too quickly. For example, when the internal wiring 24 is composed of aluminum, the etching speed when using a coolant 36 of pH=4 is approximately 100 times greater than the etching speed attained when using a coolant 36 of pH=6. Consequently, when using a coolant 36 having a pH value less than 4, excessively etched portions may be created in an end portion of the internal wiring 24, possibly causing a contact failure between the end portion and the subsequently formed external wiring 7.

Accordingly, in consideration of etching speed, it is more preferable to use a coolant 36 having a pH value ranging from 5 to 6. Carbonated water produced by bubbling carbon dioxide (CO₂) in an appropriate amount of pure water or RO water may preferably be used as the coolant 36 because the pH value of such water is maintained within a range of between 5 and 6.

As to the injecting direction of the coolant 36, it is preferable to perform the injection along the rotating direction of the dicing saw 34. With such an arrangement, the coolant 36 that contacts the cutting portion 40 flows from the cutting portion 40 to the notch 22 side along with the rotation of the dicing saw 34. In this manner, the cutting portion 40 can be further efficiently cooled, and, in addition, foreign particles can be removed from the cutting portion 40.

When performing the above process, it is preferable to spray the coolant 36 toward the cutting point 40 at an angle of elevation ranging from 5° to 45° , and more preferably from 30° to 40° , with respect to the cutting direction.

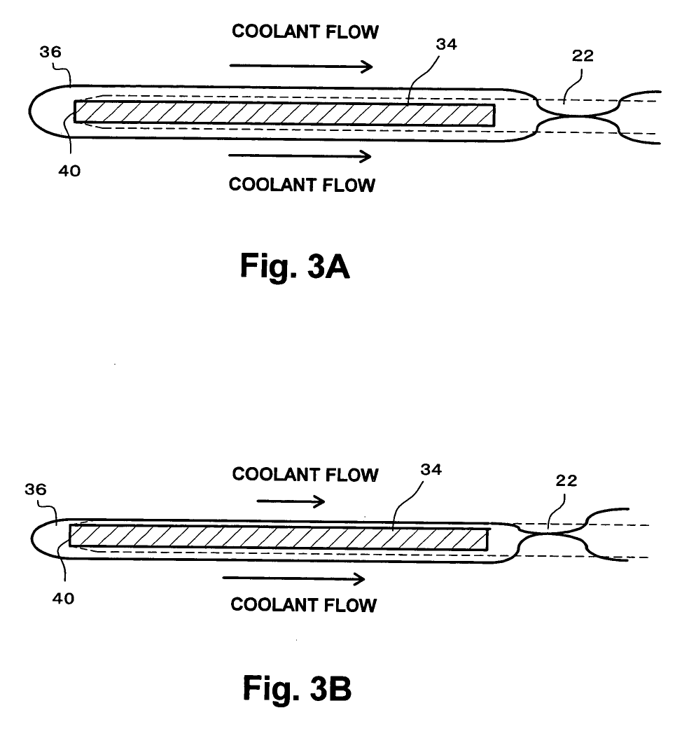

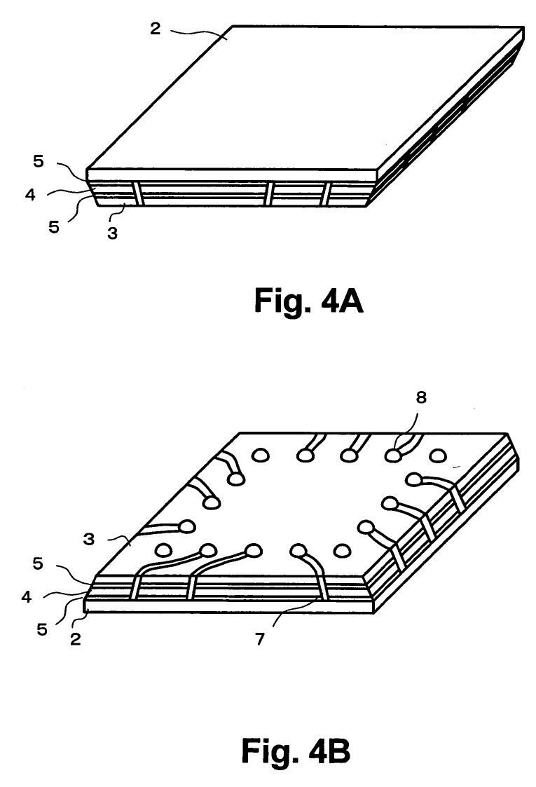

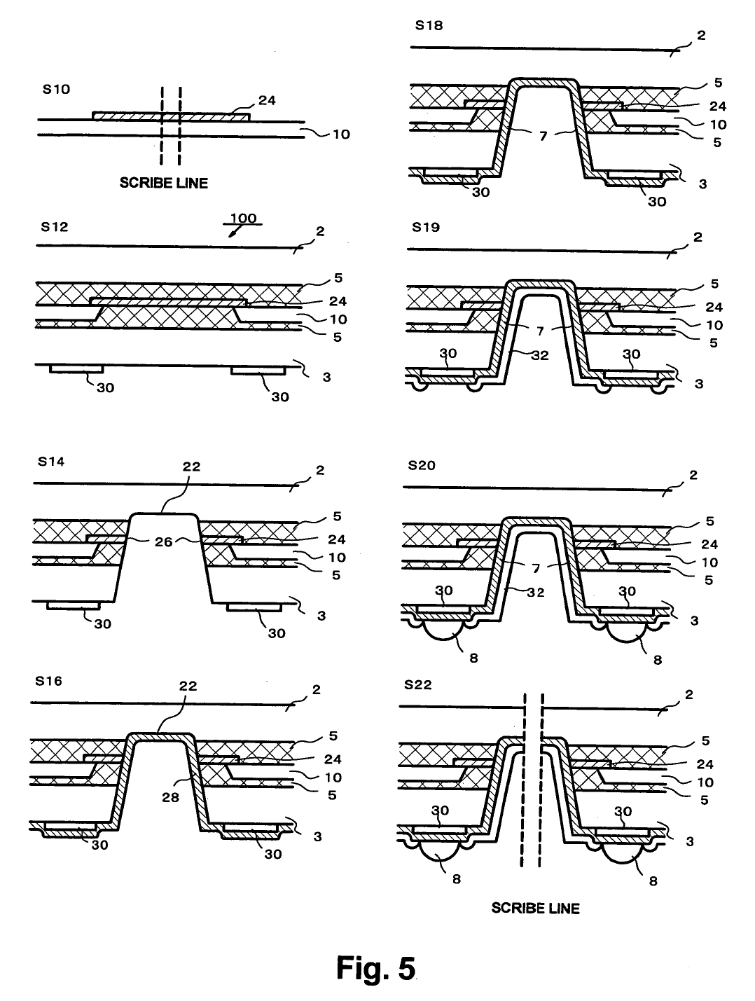

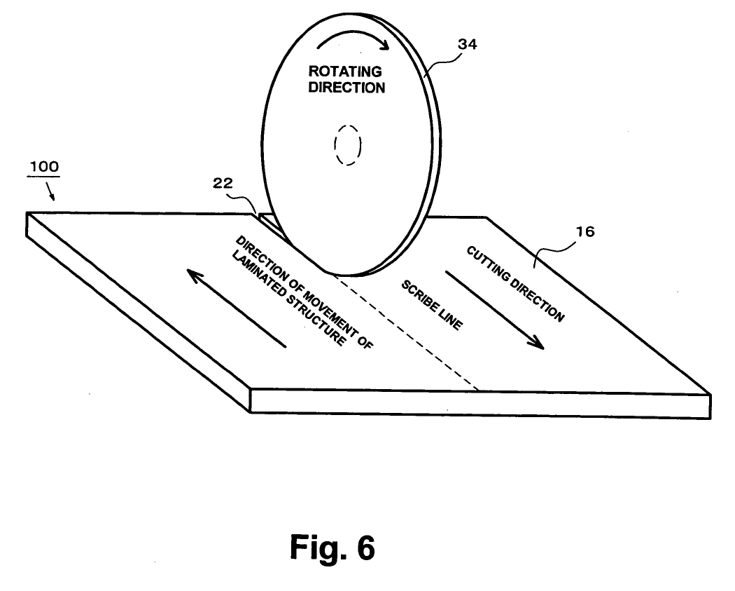

The coolant 36 is preferably sprayed at a spraying width larger than the blade width of the dicing saw 34, such that the coolant 36 completely covers the blade. With this arrangement, as shown in FIG. 3A, the coolant can be uniformly supplied to both sides of the blade of the dicing saw 34, thereby achieving efficient cooling of the dicing saw 34 during the cutting process. In contrast, when the noted conditions are not satisfied, the flow of the coolant 36 along the blade may become uneven, and the coolant 36 may not be sufficiently supplied to the inner surface of the notch 22, as shown in FIG. 3B, resulting in lower cooling efficiency.

The second coolant injector 39 is additionally positioned so as to border both sides of the dicing saw 34. As shown in FIG. 2B, the second coolant injector 39 similarly injects the coolant 36 directly on the dicing saw 34 and the cutting portion 40, thereby further enhancing cooling efficiency. This spraying of the coolant 36 from the second coolant injector 39 is also preferably performed at an angle of elevation ranging from 5° to 45° with respect to the laminated structure 100.

A cleaner injector 41 is positioned behind the dicing saw 34. By spraying a cleaner 42 on the laminated structure 100 after the cutting process, foreign particles can be removed from the notch 22 and the surface of the laminated structure 100. The cleaner 42 may comprise the same kind of material as the coolant 36.

An example laminated structure 100 including a silicon semiconductor layer sandwiched between epoxy resin layers and glass carrier members was cooled using the above-described arrangement during the cutting processing. A dicing saw 34 having a diameter of 20 cm and a blade width of 0.62 mm was operated at 40,000 rpm. 20 liters/min of pure water was sprayed toward the cutting portion 40 at an angle of elevation within a range between 30° and 40° . In this manner, the cutting process could be performed while maintaining the temperature of the cutting portion 40 below 150° C., which was the softening temperature of the epoxy resin layers, the layer with the lowest softening temperature.

By using the semiconductor device manufacturing method according to the preferred embodiment of the present invention, temperature increase of the inner surface of the notch 22 during the cutting processing can be suppressed, thereby preventing materials from undesirably adhering to the inner surface of the notch 22. As a result, the density of the metal film subsequently formed thereon can be increased, preventing corrosion and peeling of the external wiring.

According to the above arrangement, corrosion and peeling of the external wiring generated due to the cutting process can be prevented in a semiconductor device having a laminated structure formed by adhering a carrier member on a semiconductor substrate with an insulating resin interposed between the semiconductor substrate and the carrier member. As a result, reliability of the semiconductor device can be enhanced. This advantage is especially appreciated in a semiconductor device including a resin layer having a low softening temperature.

What is claimed is:

1. A semiconductor device manufacturing method, comprising:
a first step of forming a laminated structure by adhering, on a semiconductor substrate including a plurality of integrated circuits, a carrier member covering a region in which the plurality of integrated circuits are formed, with an insulating resin interposed between the semiconductor substrate and the carrier member;
a second step of cutting on the laminated structure so as to cut the semiconductor substrate together with the insulating resin while allowing at least a portion of the carrier member to remain uncut; and
a third step of dividing the laminated structure by cutting the carrier member; wherein
the second step is performed while cooling a dicing saw used to cut into the laminated structure including the semiconductor substrate.

2. A semiconductor device manufacturing method as defined in claim 1, wherein the second step is performed while the cooling is executed by spraying a coolant on the dicing saw.

3. A semiconductor device manufacturing method as defined in claim 2, wherein the second step includes spraying the coolant on the dicing saw along a rotating direction of the dicing saw at an angle of elevation of between 5° and 45°, inclusive.

4. A semiconductor device manufacturing method as defined in claim 2, wherein the second step includes spraying the coolant with a spraying width larger than the width of the dicing saw.

5. A semiconductor device manufacturing method as defined in claim 2, wherein the coolant used in the second step is obtained by passing tap water through an RO film.

6. A semiconductor device manufacturing method as defined in claim 2, wherein the second step is performed while the cooling is executed by spraying on the dicing saw a coolant having a pH value of between 4 and 6, inclusive.

7. A semiconductor device manufacturing method as defined in claim 1, further comprising:
a step of forming metal wiring on a machined surface of the laminated structure created in the second step.
